(19) United States
(12) Patent Application Publication
(10) Pub. No.: US 2015/0188510 A1
(43) Pub. Date: Jul. 2, 2015

(54) CIRCUIT STRUCTURE

(71) Applicant: SILICONWARE PRECISION INDUSTRIES CO., LTD, Taichung (TW)

(72) Inventors: Ho-Chuan Lin, Taichung (TW); Chia-Chu Lai, Taichung (TW); Min-Han Chuang, Taichung (TW); Li-Fang Lin, Taichung (TW); Ming-Fan Tsai, Taichung (TW)

(73) Assignee: SILICONWARE PRECISION INDUSTRIES CO., LTD, Taichung (TW)

(21) Appl. No.: 14/210,789

(22) Filed: Mar. 14, 2014

(30) Foreign Application Priority Data
Jan. 2, 2014 (TW) 103100021

(51) Int. Cl. H03H 7/01

(52) U.S. Cl. CPC H03H 7/1741; H03H 7/0115

(57) ABSTRACT

A circuit structure is provided, which includes: a first circuit portion having at least a capacitor; a first dielectric portion combined with the first circuit portion; a second circuit portion electrically connected to the first circuit portion and having at least an inductor; and a second dielectric portion combined with the second circuit portion, wherein the first dielectric portion has a greater dielectric constant than the second dielectric portion, thereby increasing the capacitance value and density and causing the inductor to have a high enough Q value.

### BACKGROUND OF THE INVENTION

1. Field of the Invention

The present invention relates to circuit structures with low insertion loss, and more particularly, to a circuit structure having capacitors and inductors.

2. Description of Related Art

Since portable electronic products in communications, networks, and computers and peripherals are developed to follow the trend: miniaturization, multi-function, high performance, and high integration, high-density package structures become a focus of R&D efforts of many manufacturers.

Conventional integrated passive devices (IPDs), such as low pass filters, high pass filters, band pass filters, diplexers, and baluns, comprise a combination of a plurality of inductors and a plurality of capacitors connected in series and in parallel.

FIG. 1A shows a circuit structure 1 of a conventional IPD fabricated through a bumping structure process. Referring to FIG. 1A, dielectric layers 13 made of polybenzobisoxazole (PBO) are formed on a carrier portion 19, and a circuit portion 11 is formed by lithography and electroplating in the dielectric layers 13. The circuit portion 11 has at least a capacitor 11a′, an electric trace layer 110, conductive vias 111, 111′ and at least an inductor 122, which form an LC resonant circuit.

The carrier portion 19 has a base body 190 made of silicon (for example, a silicon wafer) and a base material 191 such as PBO formed on the base body 190.

The capacitor 11a′ is formed of metal-insulator-metal (MIM) layers. In particular, a capacitor plate 110a of the electric trace layer 110 is separated from the conductive via 111′ by an isolation layer 10a′ made of such as SiNx, thus forming the capacitor 11a′.

The inductor 122 has a spiral structure, as shown in FIG. 1A′, and is electrically connected to the capacitor 11a′ through the conductive via 111. The inductor 122 has two signal ports 122a, 122b, i.e., input and output ports.

The dielectric layers 13 have a same dielectric constant. A plurality of openings are formed in the dielectric layers 13 for exposing the signal ports 122a, 122b. Further, a plurality of conductive elements 14 made of a solder material can be formed on the signal ports 122a, 122b for connecting another electronic device.

Through the bumping structure process, the inductor 122 of the circuit structure 1 can achieve a high Q value. However, since both the inductor 122 and the capacitor 11a′ are formed in the dielectric layers 13, the size of the conductive via 111′ of the capacitor 11a′ is not easy to control. That is, the size of the opening of the dielectric layer 13 for forming the conductive via 111′ is not easy to control. Therefore, the tolerance of the capacitance value increases, and the capacitance value and density are not high enough to meet the requirement.

FIG. 1B shows a circuit structure 1′ of a conventional IPD fabricated through a dual damascene process. Referring to FIG. 1B, an insulating portion 10 is formed on a carrier portion 19, and a circuit portion 12 is formed in the insulating portion 10 through a semiconductor process. The circuit portion 12 has capacitors 11a to 11c, electric trace layers 120, conductive vias 121 and an inductor 122 so as to form an LC resonant circuit.

The carrier portion 19 has a base body 190 made of silicon (for example, a silicon wafer) and a base material 191′ such as an oxide material (for example, SiO₂) formed on the base body 190.

The insulating portion 10 has a plurality of insulating layers 10a to 10f. The insulating layers 10a to 10f are made of SiO₂ and have same dielectric constants. Through a chemical vapor deposition (CVD) process, a plurality of isolation layers 10a′ to 10e′ made of silicon nitride are formed between the insulating layers 10a to 10f to serve as passivation layers.

The electric trace layers 120 and the conductive vias 121 are embedded in the insulating layers 10a to 10f and the isolation layers 10a′ to 10e′ are positioned between the electric trace layers 120 to prevent the electric trace layers 120 from coming into contact with each other. The electric trace layers 120 are electrically connected to each other through the conductive vias 121.

To form the capacitors 11a to 11c, a plurality of capacitor plates 110a to 110d are formed in the adjacent electric trace layers 120 and electrically connected through conductive vias 121′, 121″. The capacitors 11a to 11c are formed of MIM layers. For example, the capacitor 11a is constituted by the upper and lower capacitor plates 110a, 110b and the isolation layer 10a′. As such, the capacitors 11a to 11c that are connected in parallel are formed. In particular, the capacitor plates 110a and 110c are connected through the conductive via 121′ and the capacitor plates 110b and 110d are connected through the conductive via 121″.

The inductor 122 has a spiral structure, as shown in FIG. 1A′, and is formed in and exposed from the outermost insulating layer 10f. The inductor 122 is electrically connected to the capacitors 11a to 11c through the conductive vias 121.

According to the practical application need, a various number of capacitor layers can be fabricated through the dual damascene process so as to achieve a high capacitance density.

In the dual damascene process, the inductor 122 and the capacitors 11a to 11c are formed in a semiconductor material. The size of the conductive vias 121′, 121″ of the capacitors 11a to 11c is easy to control. That is, the size of the openings of the insulating layers 10b, 10c for forming the conductive vias 121′, 121″ is easy to control. Therefore, the tolerance of the capacitance value is reduced, and the capacitance value and density are high enough to meet the requirement. However, given a same inductance value, the inductor 122 of the circuit structure 1′ has a Q value lower than the inductor 122 of the circuit structure 1.

The conventional IPDs, such as band pass filters, are applicable in a wireless communication system and need to operate in multiple frequency bands. FIG. 2A is a circuit diagram of a conventional band pass filter. The band pass filter has three inductors L1 to L3, three capacitor groups C1 to C3, an input port 90 and an output port 91. The values of the capacitor groups C1 to C3 and the inductors L1 to L3 are shown as follows.

| Element | Inductance value | Capacitance value |
|---|---|---|
| L1 | 2.5 nH | |
| L2 | 1.505 nH | |
| L3 | 2.5 nH | |
| C1 | | 3.5 pF |
| C2 | | 0.5 pF |
| C3 | | 3.5 pF |

Referring to FIG. 2B, the LC resonant circuit of the band pass filter is fabricated through the process of FIG. 1A. For example, the capacitor group C1 is constituted by a single capacitor 11a′.

Referring to FIG. 2C, the LC resonator circuit of the band pass filter is fabricated through the process of FIG. 1B. Conductive traces 92 are formed of the electric trace layer 120. Further, for example, the capacitor group C1 is constituted by a plurality of capacitors 11a to 11c that are connected in parallel.

However, given certain values of the inductors L1 to L3 and the capacitor groups C1 to C3, if the size of the IPD applied in the communication system is reduced to about 1000×1000 μm², the Q value of the inductor 122 of the circuit structure 1′ decreases and therefore the insertion loss of the IPD increases (as detailed in FIG. 5B). As such, the IPD is easily interfered by noises.

Therefore, how to overcome the above-described disadvantages has become critical.

### SUMMARY OF THE INVENTION

In view of the above-described disadvantages, the present invention provides a circuit structure, which comprises: a first circuit portion having at least a capacitor; a first dielectric portion combined with the first circuit portion; a second circuit portion electrically connected to the first circuit portion and having at least an inductor; and a second dielectric portion combined with the second circuit portion, wherein the first dielectric portion has a greater dielectric constant than the second dielectric portion.

In an embodiment, the second dielectric portion is stacked on the first dielectric portion so as to cover the first circuit portion, and the first circuit portion and the second circuit portion are electrically connected to each other through electric trace layers, conductive vias or a combination thereof.

In an embodiment, the first dielectric portion and the second dielectric portion adjoin each other relative to a surface, and the first circuit portion and the second circuit portion are electrically connected to each other through electric trace layers, conductive vias or a combination thereof.

In an embodiment, the first dielectric portion and the second dielectric portion are separated from each other, and the first circuit portion and the second circuit portion are electrically connected to each other through electric trace layers, conductive vias or a combination thereof.

In an embodiment, the capacitor is electrically connected to the inductor. The inductor has a spiral structure. A plurality of signal ports are formed in the second circuit portion and electrically connected to the inductor.

In an embodiment, the first circuit portion has a plurality of capacitors and a plurality of electric trace layers, conductive vias or a combination thereof electrically connected to between at least two of the capacitors.

In an embodiment, the second circuit portion has a plurality of inductors and a plurality of electric trace layers, conductive vias or a combination thereof electrically connected to between at least two of the inductors.

In an embodiment, the first dielectric portion has a plurality of dielectric layers and the first circuit portion has a plurality of electric trace layers combined with the dielectric layers. The dielectric layers can be made of a semiconductor material or an oxide material. Two capacitor plates can be formed in adjacent electric trace layers, respectively, so as to form the capacitor. The electric trace layers can be electrically connected to each other through a plurality of conductive vias formed in the dielectric layers. Preferably, the first dielectric portion has a plurality of isolation layers formed on the dielectric layers and between the electric trace layers. The isolation layers can be nitride layers.

In an embodiment, the second dielectric portion is made of a photosensitive dielectric material.

In an embodiment, the second dielectric portion has a plurality of dielectric layers and the second circuit portion has a plurality of electric trace layers combined with the dielectric layers. Further, the electric trace layers are electrically connected to each other through a plurality of conductive vias formed in the dielectric layers, and the inductor is positioned in the outermost circuit layer.

The circuit structure can further comprise a carrier portion supporting the first dielectric portion and the second dielectric portion. The carrier portion can be made of a semiconductor material, ceramic or glass.

Therefore, by forming the capacitor in the first dielectric portion and forming the inductor in the second dielectric portion, the present invention increases the capacitance value and density and achieves a high enough Q value.

### BRIEF DESCRIPTION OF DRAWINGS

FIG. 1A is a schematic cross-sectional view of a conventional circuit structure;

FIG. 1A′ is a schematic perspective view of a conventional inductor;

FIG. 1B is a schematic cross-sectional view of another conventional circuit structure;

FIG. 2A is a schematic circuit diagram of a conventional band pass filter;

FIG. 2B is a schematic perspective view of the circuit structure of the band pass filter fabricated according to FIG. 1A;

FIG. 2C is a schematic perspective view of the circuit structure of the band pass filter fabricated according to FIG. 1B;

FIGS. 3A to 3A″ are schematic cross-sectional views of a circuit structure according to different embodiments of the present invention;

FIG. 3B is a schematic perspective view of a capacitor of the present invention;

FIG. 3C is a schematic perspective view of an inductor of the present invention;

FIG. 4A is a schematic circuit diagram of a band pass filter of the present invention;

FIG. 4B is a schematic perspective view of the circuit structure of the band pass filter fabricated according to FIG. 3A;

FIG. 5A is a schematic diagram showing the operational principle of the band pass filter of FIG. 4A;

FIG. 5B is a schematic diagram showing the insertion loss vs. frequency relationship of the conventional band pass filter and the band pass filter of the present invention; and

FIGS. 6A to 6D are schematic circuit diagrams of different IPDs using the circuit structure of the present invention.

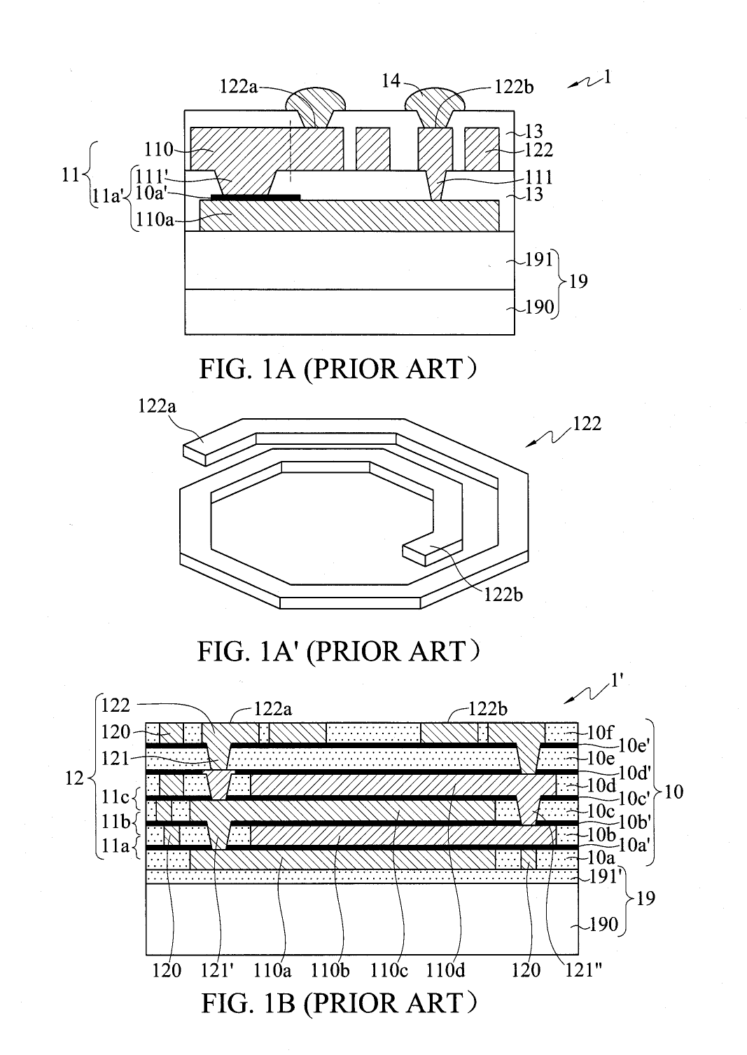

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

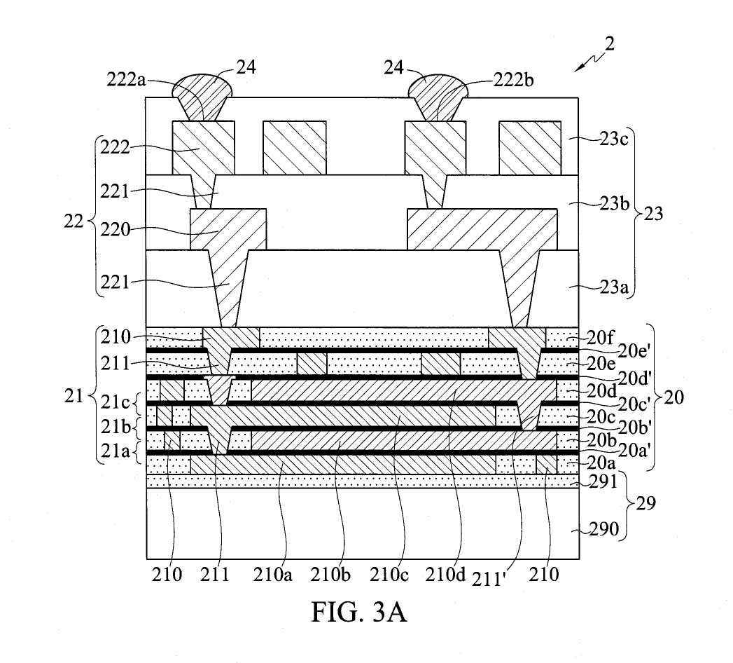

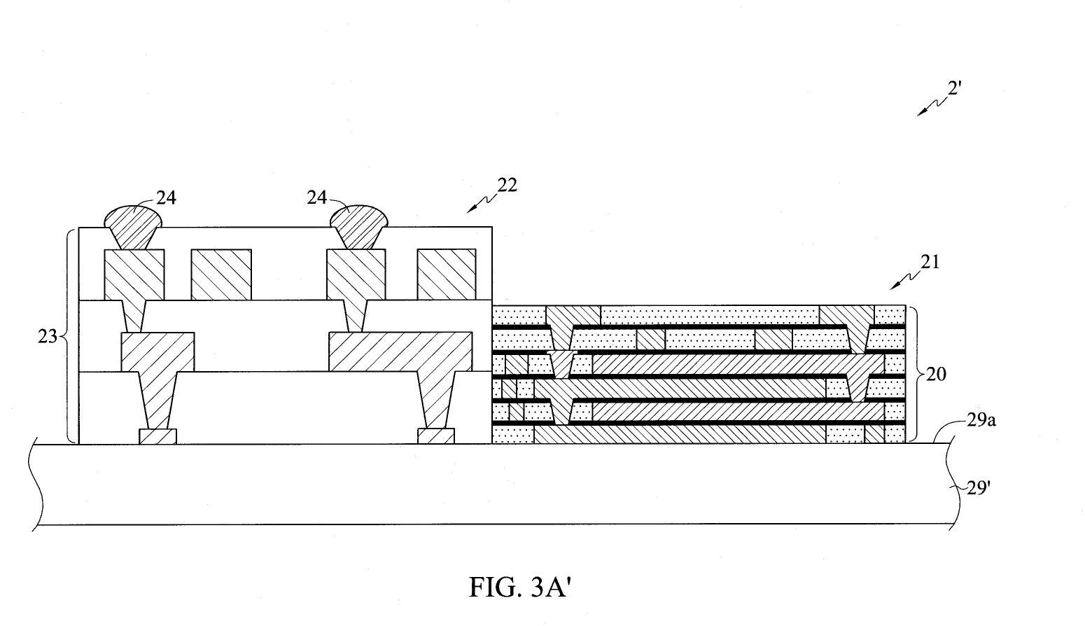

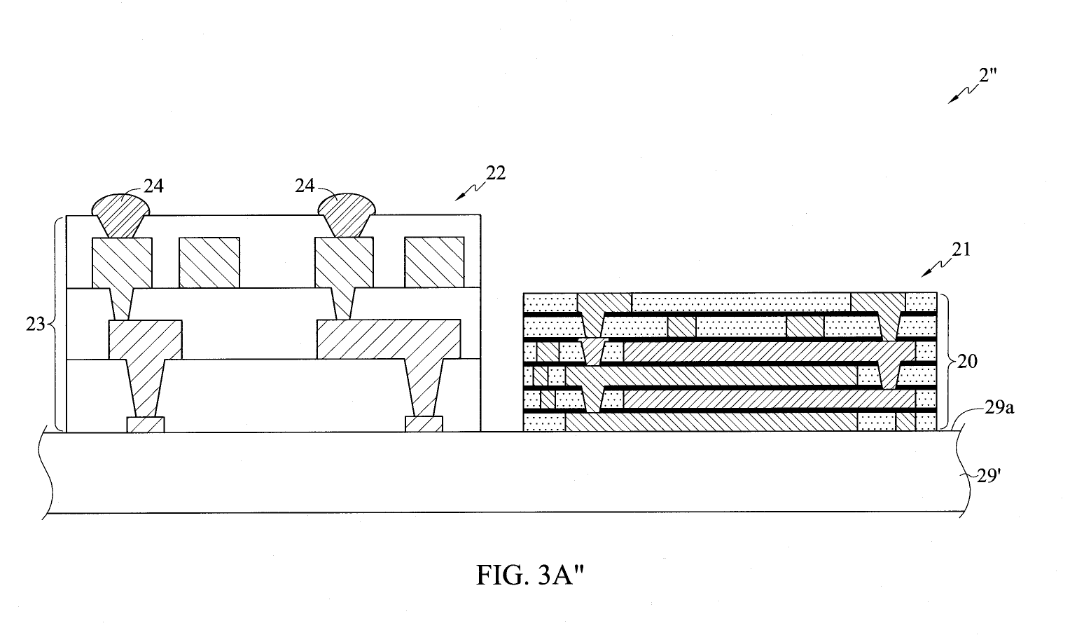

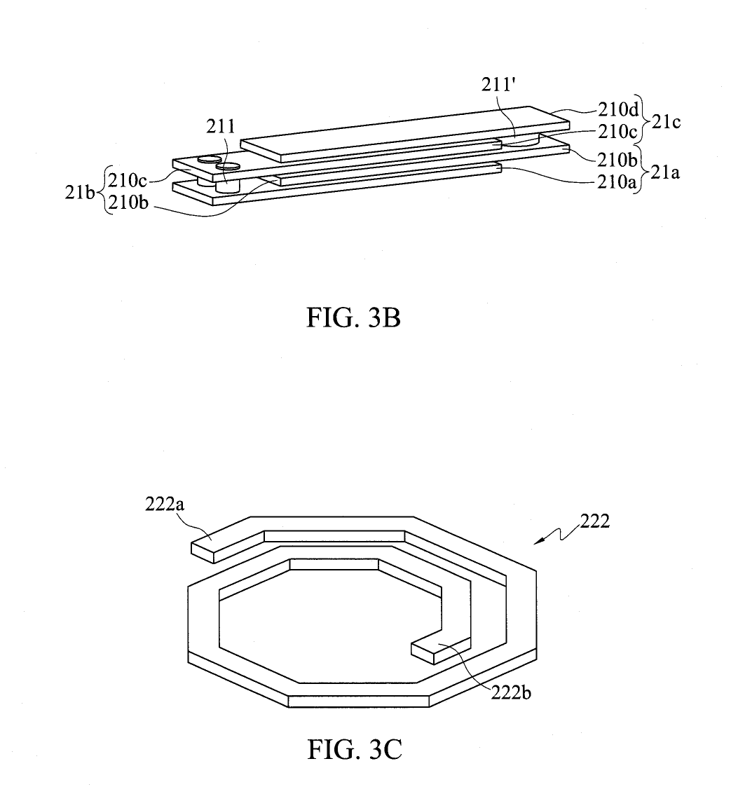

FIGS. 3A to 3A″ show a circuit structure according to different embodiments of the present invention. Referring to FIGS. 3A to 3A″, the circuit structure 2, 2′, 2″ has: a first circuit portion 21, a first dielectric portion 20 combined with the first circuit portion 21, a second circuit portion 22, a second dielectric potion 23 combined with the second circuit portion 22, and a carrier portion 29, 29′ supporting the first dielectric portion 20 and the second dielectric portion 23. The first dielectric portion 20 has a greater dielectric constant than the second dielectric portion 23.

Referring to FIG. 3A, the second dielectric portion 23 is stacked on the first dielectric portion 20 so as to cover the first circuit portion 21. The first and second circuit portions 21, 22 are electrically connected to each other through electric trace layers, conductive vias or a combination thereof.

Referring to FIG. 3A′, the first and second dielectric portions 20, 23 adjoin each other relative to a surface 29a of the carrier portion 29′. The first and second circuit portions 21, 22 are electrically connected to each other through electric trace layers, conductive vias or a combination thereof.

Referring to FIG. 3A″, the first and second dielectric portions 20, 23 adjoin each other on a surface 29a of the carrier portion 29′ and separated from each other. The first and second circuit portions 21, 22 are electrically connected to each other through electric trace layers, conductive vias or a combination thereof.

The carrier portion 29 has a base body 290 and a base material 291. In the present embodiment, the base body 290 is made of a semiconductor material, ceramic or glass. The base material 291 is an oxide material, such as silicon oxide. The carrier portion 29′ can further have electric trace layers, conductive vias or a combination thereof for electrically connecting the first and second circuit portions 21, 22.

The first dielectric portion 20 has a plurality of first dielectric layers 20a to 20f. The first dielectric layers 20a to 20f are made of an inorganic material, for example, a semiconductor material or an oxide material. In particular, the first dielectric layers 20a to 20f are made of silicon oxide, silicon nitride, aluminum oxide, silicon carbide, GaAs or GaP.

In the present embodiment, the first dielectric portion 20 has a plurality of isolation layers 20a′ to 20e′ formed between the first dielectric layers 20a to 20f. The isolation layers 20a′ to 20e′ are nitride layers, such as silicon nitride. Through a CVD process, the isolation layers 20a′ to 20e′ can be formed to serve as passivation layers.

The first circuit portion 21 has a plurality of capacitors 21a to 21c, a plurality of first electric trace layers 210 and a plurality of first conductive vias 211. The first electric trace layers 210 are combined with the first dielectric layers 20a to 20f, and the first electric trace layers 210 are electrically connected to each other through the first conductive vias 211.

In the present embodiment, referring to FIG. 3B, a plurality of capacitor plates 210a to 210d (for example, rectangular-shaped metal plates) are formed in the adjacent first electric trace layers 210 and electrically connected through the first conductive vias 211 so as to form the capacitors 21a to 21c connected in parallel, thereby increasing the capacitance value. In particular, the capacitor plates 210a and 210c are connected to each other through the first conductive via 211 and the capacitor plates 210b and 210d are connected to each other through the first conductive via 211′. In another embodiment, the capacitors 21a to 21c can be connected in series and the first electric trace layers 210, the first conductive vias 211 or a combination thereof are electrically connected to between at least two of the capacitors 21a to 21c.

Further, the capacitors 21a to 21c can be formed of MIM layers. In another embodiment, the isolation layers 20a′ to 20e′ can be omitted. Instead, the first dielectric layers 20a to 20c are formed between the capacitor plates 210a to 210d for isolation.

Further, the first electric trace layers 210 and the first conductive vias 211 are embedded in the first dielectric layers 20a to 20f and the isolation layers 20a′ to 20e′ are formed between the first electric trace layers 210 to prevent the first electric trace layers 210 from coming into contact with each other.

The second dielectric portion 23 has a plurality of second dielectric layers 23a to 23c. The second dielectric layers 23a to 23c are made of an organic material, such as a photosensitive dielectric material or a common dielectric material. In particular, the photosensitive dielectric material is divided into three types: photosensitive spin-on dielectric (PSOD) material, photodefinable material and photosensitive patternable material.

For example, the photosensitive spin-on dielectric material can be a photodefinable PBO precursor, photosensitive PDMS or photosensitive polymer poly(diphenyl bicyclohept-5-ene-2,3-dicarboxylate) (PPNB).

The photodefinable material can be a polyimide precursor, epoxycyclohexyl polyhedral oligomeric silsesquioxanes (POSS), photocatalyst or PBO.

The photosensitive patternable material can be a polysilsesquiazane composition or a photopatternable low-k dielectric material such as benzocyclobutene (BCB).

The second circuit portion 22 has an inductor 222, a plurality of second electric trace layers 220 and a plurality of second conductive vias 221. The second electric trace layers 220 are combined with the second dielectric layers 23a to 23c and the second electric trace layers 220 are electrically connected to the first electric trace layers 210 through the second conductive vias 221.

In the present embodiment, the second electric trace layers 220 are formed on the second dielectric layers 23a, 23b.

Further, referring to FIG. 3C, the inductor 222 has a spiral structure and two signal ports 222a, 222b, i.e., an input port and an output port.

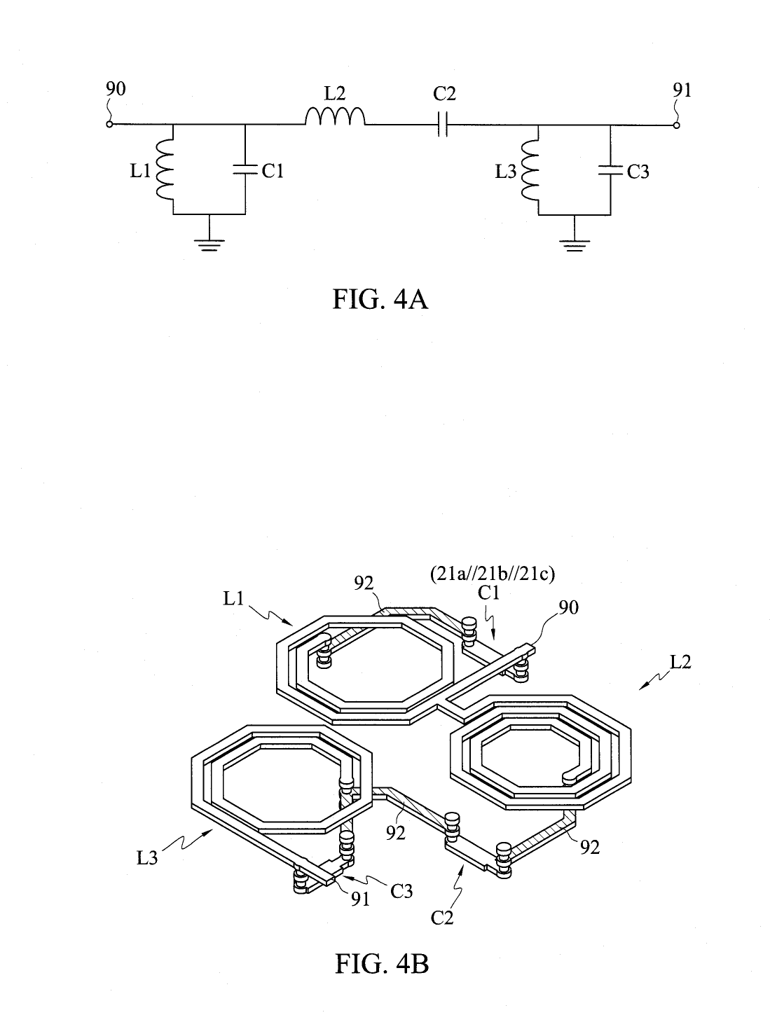

The inductor 222 is a portion of the outermost second circuit layer 220 and electrically connected to the capacitors 21a to 21c through the second conductive vias 221, the inner second electric trace layers 220, the first electric trace layers 210 and the first conductive vias 211. In other embodiments, the second circuit portion 220 can have a plurality of inductors 222 (for example, inductors L1 to L3 of FIG. 4B) and the second electric trace layers 220, the second conductive vias 221 or a combination thereof are electrically connected (in series or in parallel) to between at least two of the inductors 222.

The outermost second dielectric layer 23c of the second dielectric portion 23 has a plurality of openings for exposing the signal ports 222a, 222b. Further, a plurality of conductive elements 24 made of such as a solder material can be formed on the signal ports for connecting another electronic device.

The first dielectric portion 20 has a greater dielectric constant than the second dielectric portion 23. The capacitors 21a to 21c are formed in the first dielectric portion 20 through a dual damascene process such that the size of the conductive vias 211, 211′ is easy to control. That is, the size of the openings of the first dielectric layers 20b, 20c for forming the conductive vias 211, 211′ is easy to control. As such, the tolerance of the capacitance value is reduced and the capacitance value and density per unit area are increased. Further, the inductor 222 has a high enough Q value.

The inductor 222 can be formed in the second dielectric portion 23 through a bumping structure process so as to achieve a high Q value.

Therefore, by performing a dual damascene process to form the capacitors 21a to 21c first and then performing a bumping structure process to form the inductor 222, the present invention allows the inductor 222 and the capacitors 21a to 21c to be connected according to the required circuit structure of an IPD.

For example, a band pass filter applied in a wireless communication system needs to operate in multiple frequency bands. Referring to FIG. 4A, the band pass filter has three inductors L1 to L3, three capacitor groups C1 to C3, conductive traces 92, an input port 90 and an output port 91. Referring to FIG. 4B, the band pass filter has an LC resonant circuit fabricated according to the process of FIG. 3A. The conductive traces 92 are formed of the first circuit layer 210 or the second circuit layer 220. Further, for example, the capacitor group C1 is constituted by the capacitors 21a to 21c that are connected in parallel.

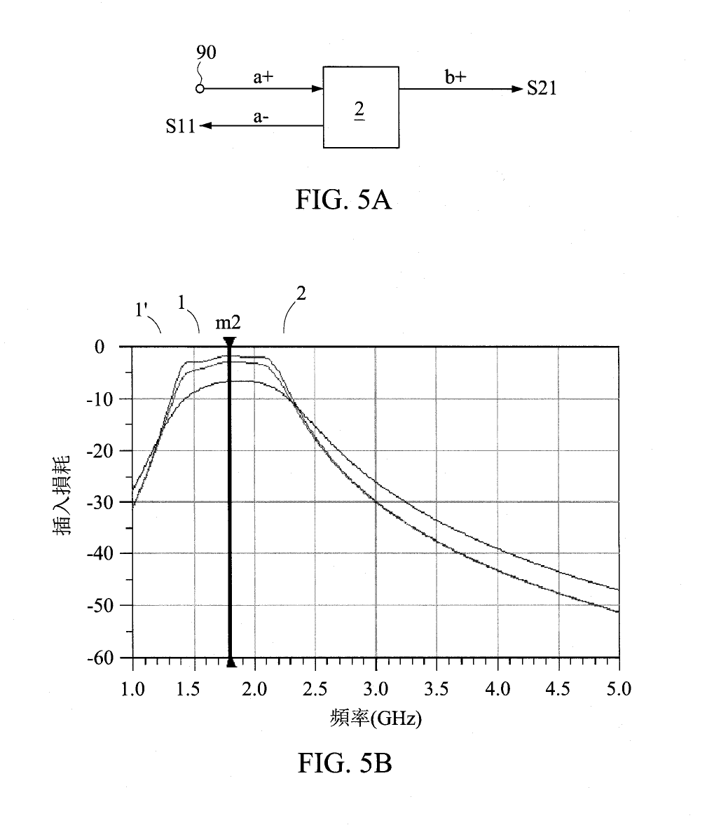

FIG. 5A shows the operational principle of the band pass filter of FIG. 4A. Referring to FIG. 5A, a⁺ refers to incidence power, a⁻ refers to reflection power, b⁺ refers to transmission power, S11 refers to return loss, S21 refers to insertion loss, which is an output port 91. Further, S11=10 log[a⁻/a⁺], S21=10 log[b⁺/a⁺].

FIG. 5B shows the insertion loss vs. frequency relationship of a conventional band pass filter and the band pass filter of the present invention. Referring to FIG. 5B, the curves of different band pass filters are represented by the corresponding circuit structures 1, 1′, 2, respectively. Further, m2 represents a frequency of 1.8 GHz. In the experiment, the input port 90 and the output port 91 use a same reference inductance value. The insertion loss is defined as:

IL=−20 log₁₀|S21|dB

The values of the capacitor groups C1 to C3 and the inductors L1 to L3 of the band pass filters are shown as follows.

| Element | Inductance value | Capacitance value |
|---|---|---|
| L1 | 2.5 nH | |
| L2 | 1.505 nH | |
| L3 | 2.5 nH | |
| C1 | | 3.5 pF |
| C2 | | 0.5 pF |
| C3 | | 3.5 pF |

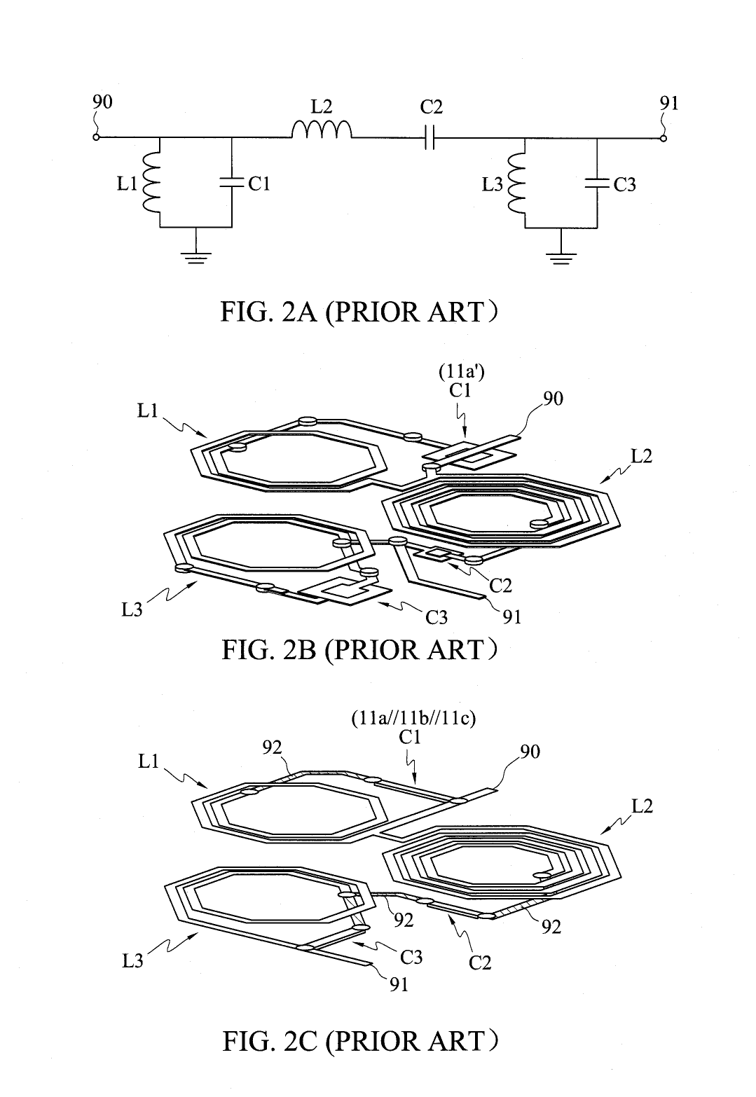

Referring to FIG. 5B, between 1.4 and 2.3 GHz, the band pass filter having the circuit structure 2 has the minimum insertion loss (a value of −1.640 at m2) and the band pass filter having the conventional circuit structure 1′ of FIG. 2B has the maximum insertion loss (a value of −6.646 at m2). Further, the band pass filter having the circuit structure 1 of FIG. 2A has an insertion loss of −2.892 at m2. Therefore, the IPD of the present invention has a reduced insertion loss so as not to be interfered by noises.

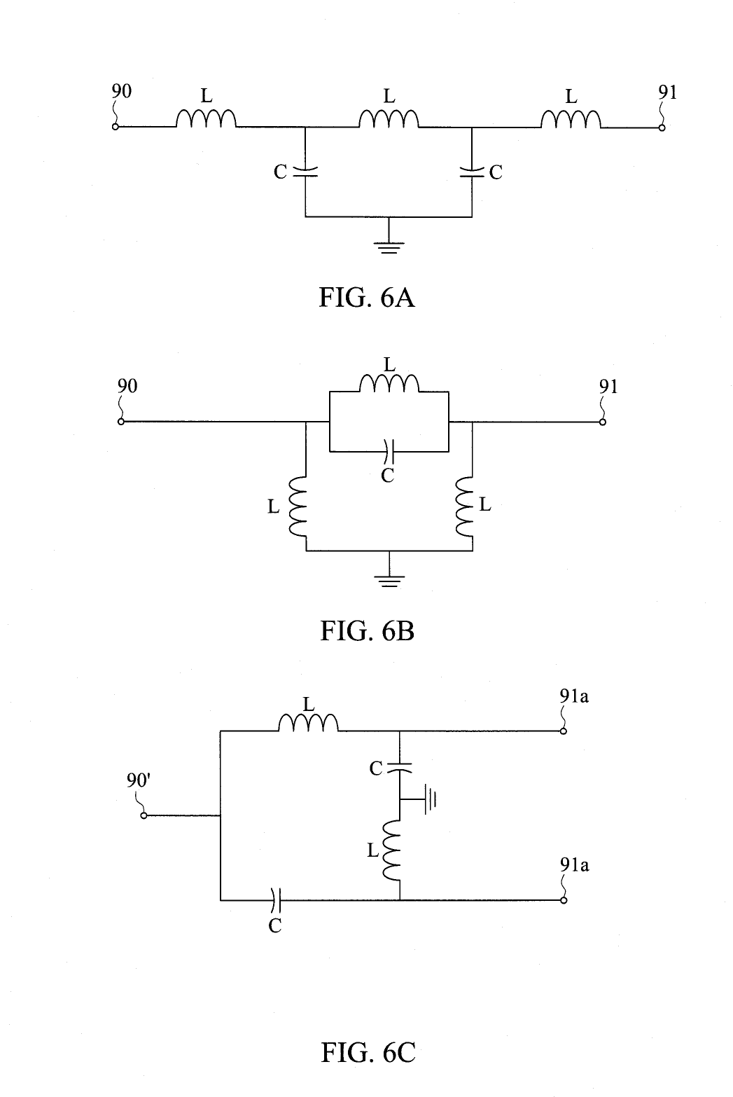

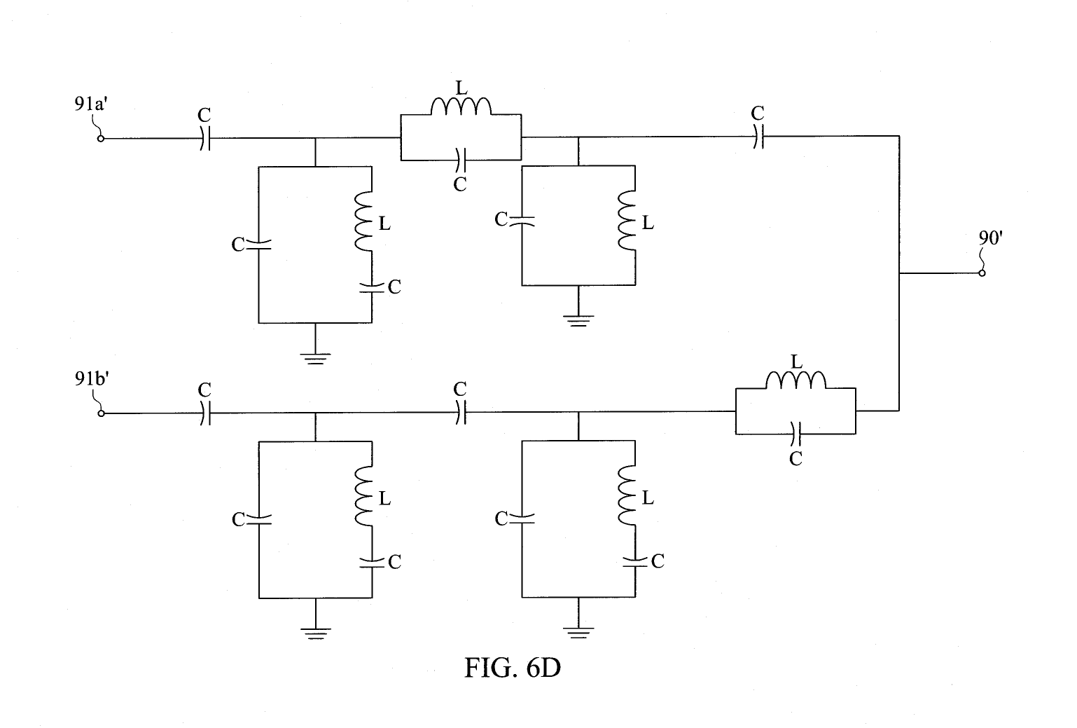

The circuit structure 2 of the present invention is applicable in various types of IPDs. FIG. 6A is a circuit diagram of a low pass filter, FIG. 6B is a circuit diagram of a high pass filter, FIG. 6C is a circuit diagram of a balun, and FIG. 6D is a circuit diagram of a diplexer.

Referring to FIG. 6C, the balun has an input port 90′, such as an unbalanced port, and two output ports 91a, 91b, such as balanced ports.

Referring to FIG. 6D, the diplexer has an input port 90′, such as an unbalanced port, and two output ports 91a′, 91b′, such as a high frequency output port and a low frequency output port.

It should be noted that the inductors L and the capacitors C of FIGS. 6A to 6D are only for illustrative purposes and values thereof can be designed according to the practical need.

According to the present invention, the capacitor is formed in the first dielectric portion and the inductor is formed in the second dielectric portion so as to increase the capacitance value and density and achieve a high enough Q value, thereby meeting the requirement of IPDs.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A circuit structure, comprising:
a first circuit portion having at least a capacitor;
a first dielectric portion combined with the first circuit portion;
a second circuit portion electrically connected to the first circuit portion and having at least an inductor; and
a second dielectric portion combined with the second circuit portion, wherein the first dielectric portion has a greater dielectric constant than the second dielectric portion.

2. The circuit structure of claim 1, wherein the second dielectric portion is stacked on the first dielectric portion so as to cover the first circuit portion.

3. The circuit structure of claim 2, wherein the first circuit portion and the second circuit portion are electrically connected to each other through electric trace layers, conductive vias or a combination thereof.

4. The circuit structure of claim 1, wherein the first dielectric portion and the second dielectric portion adjoin each other relative to a surface.

5. The circuit structure of claim 4, wherein the first circuit portion and the second circuit portion are electrically connected to each other through electric trace layers, conductive vias or a combination thereof.

6. The circuit structure of claim 1, wherein the first dielectric portion and the second dielectric portion are separated from each other.

7. The circuit structure of claim 6, wherein the first circuit portion and the second circuit portion are electrically connected to each other through electric trace layers, conductive vias or a combination thereof.

8. The circuit structure of claim 1, wherein the capacitor is electrically connected to the inductor.

9. The circuit structure of claim 1, wherein the first circuit portion has a plurality of capacitors and a plurality of electric trace layers, conductive vias or a combination thereof electrically connected to between at least two of the capacitors.

10. The circuit structure of claim 1, wherein the second circuit portion has a plurality of inductors and a plurality of electric trace layers, conductive vias or a combination thereof electrically connected to between at least two of the inductors.

11. The circuit structure of claim 1, wherein the first dielectric portion has a plurality of dielectric layers and the first circuit portion has a plurality of electric trace layers combined with the dielectric layers.

12. The circuit structure of claim 11, wherein the dielectric layers are made of a semiconductor material or an oxide material.

13. The circuit structure of claim 11, wherein two capacitor plates are formed in adjacent electric trace layers, respectively, so as to form the capacitor.

14. The circuit structure of claim 11, wherein the electric trace layers are electrically connected to each other through a plurality of conductive vias formed in the dielectric layers.

15. The circuit structure of claim 11, wherein the first dielectric portion has a plurality of isolation layers formed on the dielectric layers and between the electric trace layers

16. The circuit structure of claim 15, wherein the isolation layers are nitride layers.

17. The circuit structure of claim 1, wherein the inductor has a spiral shape.

18. The circuit structure of claim 1, further comprising a plurality of signal ports formed in the second circuit portion and electrically connected to the inductor.

19. The circuit structure of claim 1, wherein the second dielectric portion is made of a photosensitive spin on dielectrics, a photodefinable material, or a photosensitive patternable material.

20. The circuit structure of claim 1, wherein the second dielectric portion has a plurality of dielectric layers and the second circuit portion has a plurality of electric trace layers combined with the dielectric layers.

21. The circuit structure of claim 20, wherein the electric trace layers are electrically connected to each other through a plurality of conductive vias formed in the dielectric layers.

22. The circuit structure of claim 20, wherein the inductor is positioned in the outermost circuit layer.

23. The circuit structure of claim 1, further comprising a carrier portion supporting the first dielectric portion and the second dielectric portion.

24. The circuit structure of claim 23, wherein the carrier portion is made of a semiconductor material, ceramic or glass.
